(19) United States
(12) Patent Application Publication
(10) Pub. No.: US 2024/0284762 A1
(43) Pub. Date: Aug. 22, 2024

(54) ADHESIVE MEMBER AND DISPLAY DEVICE INCLUDING THE SAME

(71) Applicant: SAMSUNG DISPLAY CO., LTD., YONGIN-SI (KR)

(72) Inventors: DASONG LEE, Yongin-si (KR); WON-SEOK KIM, Yongin-si (KR); JONGDEOK PARK, Yongin-si (KR); INTAE SON, Yongin-si (KR); JAESUK YOO, Yongin-si (KR); KANG-WOO LEE, Yongin-si (KR)

(21) Appl. No.: 18/544,686

(22) Filed: Dec. 19, 2023

(30) Foreign Application Priority Data
Feb. 20, 2023 (KR) 10-2023-0022332

(51) Int. Cl. H10K 59/80; B32B 7/12; C09J 4/00; C09J 9/00; H01L 33/52

(52) U.S. Cl. CPC H10K 59/873; B32B 7/12; C09J 4/00; C09J 9/00; H01L 33/52; B32B 2307/54; B32B 2307/7376; B32B 2457/20; H01L 25/167

(57) ABSTRACT

An adhesive member includes a first adhesive layer having a first storage modulus at a temperature of about 25° C. and a second adhesive layer disposed directly on the first adhesive layer and including a first portion adjacent to the first adhesive layer and having a second storage modulus greater than the first storage modulus at the temperature of about 25° C. and a second portion spaced apart from the first portion in a thickness direction and having a third storage modulus smaller than the second storage modulus at the temperature of about 25° C.

This U.S. non-provisional patent application claims priority under 35 U.S.C. § 119 of Korean Patent Application No. 10-2023-0022332, filed on Feb. 20, 2023, the contents of which are hereby incorporated by reference in its entirety.

### BACKGROUND

### 1. Field of Disclosure

The present disclosure relates to an adhesive member and a display device including the same. More particularly, the present disclosure relates to an adhesive member including a plurality of adhesive layers and a display device including the adhesive member.

### 2. Discussion of Related Art

Various display devices include a display module with a light emitting diode or an organic electroluminescence element. The display module includes a plurality of members, for example, a plurality of optical functional films and a protective panel, and each layer in which pores are present is attached to an adhesive film such as an optically clear adhesive (OCA) film and an adhesive resin such as an optically clear resin (OCR) to improve attachment thereof.

In recent years, there has been a diversification in stacked structures and shapes of members within display devices. Research is being conducted on various types of adhesive members applicable to such display devices.

### SUMMARY

The present disclosure provides an adhesive member with excellent impact resistance and superior adhesive reliability.

The present disclosure provides a display device including the adhesive member.

According to an embodiment of the present disclosure, an adhesive member includes a first adhesive layer having a first storage modulus at a temperature of about 25° C. and a second adhesive layer disposed directly on the first adhesive layer and including a first portion adjacent to the first adhesive layer and having a second storage modulus greater than the first storage modulus at the temperature of about 25° C. and a second portion spaced apart from the first portion in a vertical direction and having a third storage modulus smaller than the second storage modulus at the temperature of about 25° C. The first adhesive layer extends in first and second horizontal directions different from each other. The vertical direction is perpendicular to the first and second horizontal directions.

The second adhesive layer has a storage modulus that increases from the second portion to the first portion.

The first storage modulus is equal to or greater than about 0.03 MPa and equal to or smaller than about 0.05 MPa at the temperature of about 25° C.

The second storage modulus is equal to or greater than about 0.1 MPa and equal to or smaller than about 0.4 MPa at the temperature of about 25° C., and the third storage modulus is equal to or greater than about 0.03 MPa and equal to or smaller than about 0.05 MPa at the temperature of about 25° C.

The adhesive member has a thickness equal to or greater than about 150 micrometers and equal to or smaller than about 200 micrometers.

The first adhesive layer has a thickness equal to or greater than about 25 micrometers and equal to or smaller than about 60 micrometers.

The second adhesive layer has a thickness equal to or greater than about 75 micrometers and equal to or smaller than about 150 micrometers.

The second adhesive layer is provided in a single layer.

The second adhesive layer includes a first photoinitiator absorbing a light having a center wavelength equal to or greater than about 220 nanometers and equal to or smaller than about 320 nanometers and a second photoinitiator absorbing a light having a center wavelength equal to or greater than about 340 nanometers and equal to or smaller than about 440 nanometers.

The first photoinitiator of the first portion has a concentration greater than a concentration of the first photoinitiator of the second portion, and the second photoinitiator of the first portion has a concentration smaller than a concentration of the second photoinitiator of the second portion.

The concentration of the first photoinitiator decreases from the first portion to the second portion.

The concentration of the second photoinitiator increases from the first portion to the second portion.

Embodiments of the inventive concept provide a display device including a display module, a window disposed on the display module, and an adhesive member disposed between the display module and the window. The adhesive member includes a first adhesive layer disposed adjacent to the display module and having a first storage modulus at a temperature of about 25° C. and a second adhesive layer disposed between the first adhesive layer and the window and including a first portion adjacent to the first adhesive layer and having a second storage modulus greater than the first storage modulus at the temperature of about 25° C. and a second portion disposed adjacent to the window and having a third storage modulus smaller than the second storage modulus at the temperature of about 25° C.

The second adhesive layer has a storage modulus that increases from the second portion to the first portion.

The first storage modulus is equal to or greater than about 0.03 MPa and equal to or smaller than about 0.05 MPa at the temperature of about 25° C.

The second storage modulus is equal to or greater than about 0.1 MPa and equal to or smaller than about 0.4 MPa at the temperature of about 25° C., and the third storage modulus is equal to or greater than about 0.03 MPa and equal to or smaller than about 0.05 MPa at the temperature of about 25° C.

The adhesive member has a thickness equal to or greater than about 150 micrometers and equal to or smaller than about 200 micrometers.

The first adhesive layer has a thickness equal to or greater than about 25 micrometers and equal to or smaller than about 60 micrometers.

The second adhesive layer has a thickness equal to or greater than about 75 micrometers and equal to or smaller than about 150 micrometers.

The second adhesive layer is provided in a single layer.

The display module includes a display panel and an input sensing unit disposed on the display panel, the adhesive member is disposed directly on the input sensing unit, and the window is disposed directly on the adhesive member.

The second adhesive layer is disposed directly on the first adhesive layer.

The second adhesive layer includes a first photoinitiator absorbing a light having a center wavelength equal to or greater than about 220 nanometers and equal to or smaller than about 320 nanometers and a second photoinitiator absorbing a light having a center wavelength equal to or greater than about 340 nanometers and equal to or smaller than about 440 nanometers.

The first photoinitiator of the first portion has a concentration greater than a concentration of the first photoinitiator of the second portion, and the second photoinitiator of the first portion has a concentration smaller than a concentration of the second photoinitiator of the second portion.

The concentration of the first photoinitiator decreases from the first portion to the second portion.

The concentration of the second photoinitiator increases from the first portion to the second portion.

According to the above, the adhesive member includes the first adhesive layer and the second adhesive layer disposed on the first adhesive layer, and the second adhesive layer has a modulus that decreases from a portion adjacent to the first adhesive layer to a portion farther away from the first adhesive layer. Accordingly, the adhesive member has excellent impact resistance and superior adhesive reliability.

According to the above, the display device includes the adhesive member including the first adhesive layer and the second adhesive layer disposed on the first adhesive layer. As the modulus of the second adhesive layer decreases from the portion adjacent to the first adhesive layer to the portion farther away from the first adhesive layer, the display device has excellent impact resistance and superior adhesive reliability.

### BRIEF DESCRIPTION OF THE DRAWINGS

The above and other advantages of the present disclosure will become readily apparent by reference to the following detailed description when considered in conjunction with the accompanying drawings wherein:

FIG. 1 is a perspective view of a display device according to an embodiment of the present disclosure;

FIG. 2A is a perspective view of a display device in an unfolded state according to an embodiment of the present disclosure;

FIG. 2B is a perspective view of the display device of FIG. 2A which is being inwardly folded according to an embodiment of the present disclosure;

FIG. 2C is a perspective view of the display device of FIG. 2A which is being outwardly folded according to an embodiment of the present disclosure;

FIG. 3A is a perspective view of a display device in an unfolded state according to an embodiment of the present disclosure;

FIG. 3B is a perspective view of the display device of FIG. 3A which is being inwardly folded according to an embodiment of the present disclosure;

FIG. 3C is a perspective view of the display device of FIG. 3A which is being outwardly folded according to an embodiment of the present disclosure;

FIG. 4 is an exploded perspective view of a display device according to an embodiment of the present disclosure;

FIG. 5 is a cross-sectional view of a display device according to an embodiment of the present disclosure;

FIG. 6A is a view of a display device according to an embodiment of the present disclosure;

FIG. 6B is an enlarged view of a portion of a display device according to an embodiment of the present disclosure;

FIG. 7 is a graph illustrating a concentration of first and second photoinitiators included in a second adhesive layer according to an embodiment of the present disclosure;

FIG. 8 is a view illustrating a method of manufacturing an adhesive member according to an embodiment of the present disclosure;

FIG. 9A is a view of a method of manufacturing an adhesive member according to an embodiment of the present disclosure;

FIG. 9B is an enlarged view of an interface between a second adhesive layer and a coating layer according to an embodiment of the present disclosure;

FIG. 10A is a view of a method of manufacturing an adhesive member according to an embodiment of the present disclosure;

FIG. 10B is an enlarged view of a portion of a second adhesive layer that is cured according to an embodiment of the present disclosure;

FIG. 11 is a view of a method of manufacturing an adhesive member according to an embodiment of the present disclosure; and

FIG. 12 is a view of a method of manufacturing an adhesive member according to an embodiment of the present disclosure.

### DETAILED DESCRIPTION

The present disclosure may be variously modified and realized in many different forms, and thus specific embodiments will be exemplified in the drawings and described in detail hereinbelow. However, the present disclosure should not be limited to the specific disclosed forms, and should be construed to include all modifications, equivalents, or replacements included in the spirit and scope of the present disclosure.

In the present disclosure, it will be understood that when an element (or area, layer, or portion) is referred to as being “on”, “connected to” or “coupled to” another element or layer, it can be directly on, connected or coupled to the other element or layer or intervening elements or layers may be present.

Like numerals refer to like elements throughout. In the drawings, the thickness, ratio, and dimension of components are exaggerated for effective description of the technical content. As used herein, the term “and/or” may include any and all combinations of one or more of the associated listed items.

It will be understood that, although the terms first, second, etc. may be used herein to describe various elements, these elements should not be limited by these terms. These terms are only used to distinguish one element from another element. Thus, a first element discussed below could be termed a second element without departing from the teachings of the present disclosure. As used herein, the singular forms, “a”, “an” and “the” are intended to include the plural forms as well, unless the context clearly indicates otherwise.

Spatially relative terms, such as “beneath”, “below”, “lower”, “above”, “upper” and the like, may be used herein for ease of description to describe one element or feature's relationship to another elements or features as shown in the figures.

It will be further understood that the terms “include” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, an adhesive member and a display device according to embodiments of the present disclosure will be described with reference to accompanying drawings.

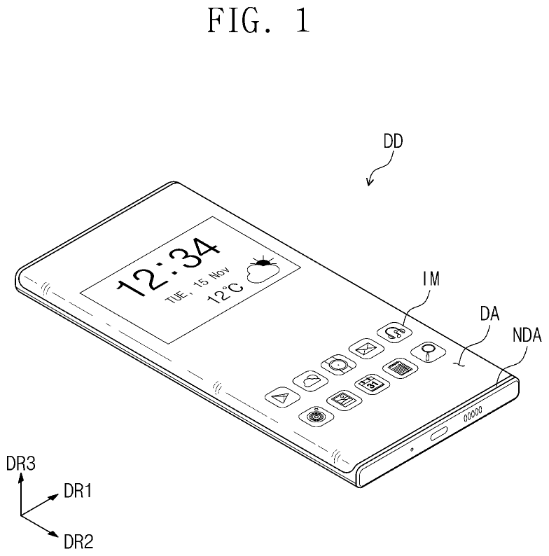

FIG. 1 is a perspective view of a display device according to an embodiment of the present disclosure.

Referring to FIG. 1, the display device DD may be a device that display an image in response to electrical signals. As an example, the display device DD may be a personal computer, a notebook computer, a personal digital assistant, a game unit, a mobile electronic device, a television, a monitor, an outdoor billboard, a car navigation unit, or a wearable device, however, it should not be limited thereto or thereby. FIG. 1 shows a mobile phone as a representative example of the display device DD.

The display device DD may display an image IM through a display area DA. The display area DA may include a plane defined by a first directional axis DR1 and a second directional axis DR2. The display area DA may further include a curved surface bent from at least one side of the plane defined by the first directional axis DR1 and the second directional axis DR2. The display device DD shown in FIG. 1 may include two curved surfaces respectively bent from opposite sides of the plane defined by the first directional axis DR1 and the second directional axis DR2, however, it should not be limited thereto or thereby. For example, the display area DA may include only the plane defined by the first directional axis DR1 and the second directional axis DR2, or the display area DA may further include two or more curved surfaces, e.g., four curved surfaces respectively bent from four sides of the plane defined by the first directional axis DR1 and the second directional axis DR2.

A non-display area NDA may be adjacent to the display area DA. The non-display area NDA may surround the display area DA. Accordingly, the display area DA may have a shape that is substantially defined by the non-display area NDA, however, this is merely one example. The non-display area NDA may be adjacent to only one side of the display area DA or may be omitted. According to an embodiment, the display device DD may include the display area of various shapes, and it should not be particularly limited.

FIG. 1 and the following drawings show first, second, and third directional axes DR1, DR2, and DR3, and directions indicated by the first, second, and third directional axes DR1, DR2, and DR3 may be relative to each other and may be changed in other directions. In addition, the directions indicated by the first, second, and third directional axes DR1, DR2, and DR3 may be referred to as first, second, and third directions, respectively, and the first, second, and third directions may be assigned with the same reference numerals as those of the first, second, and third directional axes DR1, DR2, and DR3. In the following descriptions, the first directional axis DR1 may be substantially perpendicular to the second directional axis DR2, and the third directional axis DR3 may be a normal line direction with respect to (i.e., may be perpendicular to) the plane defined by the first directional axis DR1 and the second directional axis DR2.

A thickness direction of the display device DD may be substantially parallel to the third directional axis DR3 that is the normal line direction of the plane defined by the first directional axis DR1 and the second directional axis DR2. In the present embodiment, a front surface (or an upper surface, an upper portion surface, or an upper side) and a rear surface (or a lower surface, a lower portion surface, or a lower side) of each member of the display device DD may be defined with respect to the third directional axis DR3. In addition, the front surface (or the upper surface, the upper portion surface, or the upper side) may indicate a surface (or a direction) adjacent to a surface through which the image IM is displayed, and the rear surface (or the lower surface, the lower portion surface, or the lower side) may indicate a surface (or a direction) spaced apart from the surface through which the image IM is displayed.

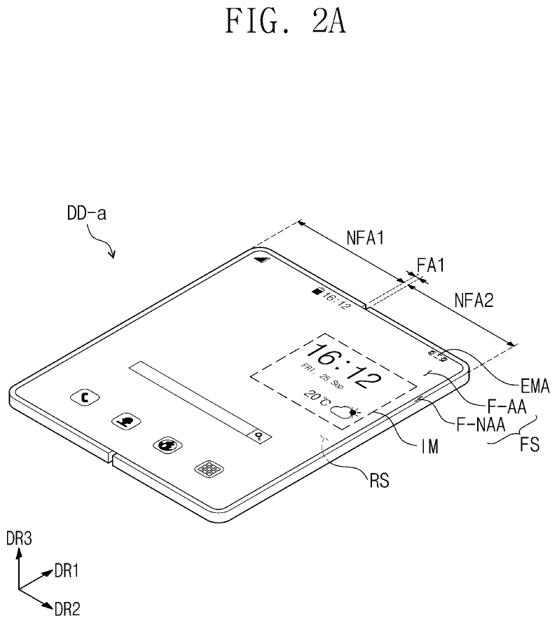

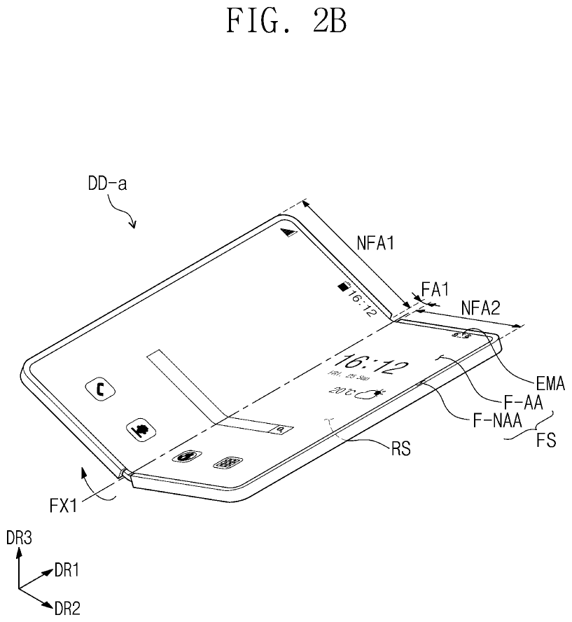

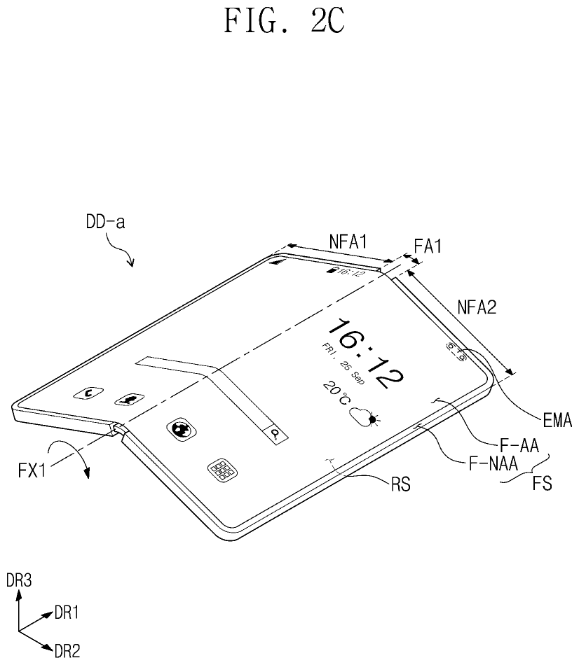

FIG. 2A is a perspective view of a display device DD-a in an unfolded state according to an embodiment of the present disclosure. FIG. 2B is a perspective view of the display device DD-a of FIG. 2A which is being inwardly folded according to an embodiment of the present disclosure. FIG. 2C is a perspective view of the display device DD-a of FIG. 2A which is being outwardly folded according to an embodiment of the present disclosure.

The display device DD-a may be a device that is activated in response to electrical signals. As an example, the display device DD-a may be a mobile phone, a tablet computer, a car navigation unit, a game unit, or a wearable device, however, it should not be limited thereto or thereby. FIG. 2A shows the mobile phone as a representative example of the display device DD-a.

Referring to FIGS. 2A to 2C, the display device DD-a may include a first display surface FS defined by a first directional axis DR1 and a second directional axis DR2 intersecting the first directional axis DR1. The display device DD-a may provide an image IM to a user through the first display surface FS. The display device DD-a may display the image IM through the first display surface FS, which is substantially parallel to each of the first directional axis DR1 and the second directional axis DR2, toward a third directional axis DR3. In the present disclosure, front (or upper) and rear (or lower) surfaces of each member of the display device DD-a may be defined with respect to a direction in which the image IM is displayed. The front and rear surfaces may be opposite to each other in the third directional axis DR3, and a normal line direction of each of the front and rear surfaces may be substantially parallel to the third directional axis DR3.

According to an embodiment, the display device DD-a may include the first display surface FS and a second display surface RS. The first display surface FS may include an active area F-AA and a peripheral area F-NAA. The active area F-AA may include an electronic module area EMA. The second display surface RS may be opposite to at least a portion of the first display surface FS. For example, the second display surface RS may be defined as a portion of a rear surface of the display device DD-a.

The display device DD-a may sense an external input applied thereto from the outside of the display device DD-a. The external input may include various forms of inputs provided from the outside of the display device DD-a. As an example, the external inputs may include an external input (e.g., hovering) applied when approaching close to or adjacent to the display device DD-a at a predetermined distance as well as a touch input by a user's body part (e.g., a user's hand). In addition, the external inputs may be provided in the form of force, pressure, temperature, light, etc.

FIG. 2A and the following drawings show the first, second, and third directional axes DR1, DR2, and DR3, and directions indicated by the first, second, and third directional axes DR1, DR2, and DR3 may be relative to each other and may be changed to other directions. In addition, the directions indicated by the first, second, and third directional axes DR1, DR2, and DR3 may be referred to as first, second, and third directions, respectively, and the first, second, and third directions may be assigned with the same reference numerals as those of the first, second, and third directional axes DR1, DR2, and DR3.

The active area F-AA of the display device DD-a may be activated in response to the electrical signals. The display device DD-a may display the image IM through the active area F-AA, and various external inputs may be sensed through the active area F-AA. The peripheral area F-NAA may be adjacent to the active area F-AA. The peripheral area F-NAA may have a predetermined color. The peripheral area F-NAA may surround the active area F-AA. Accordingly, the active area F-AA may have a shape that is substantially defined by the peripheral area F-NAA, however, this is merely an example. The peripheral area F-NAA may be adjacent to only one side of the active area F-AA or may be omitted. According to an embodiment, the display device DD-a may include the active area of various shapes, and it should not be particularly limited.

The display device DD-a may include a folding area FA1 and non-folding areas NFA1 and NFA2. According to the present embodiment, the non-folding areas NFA1 and NFA2 may be adjacent to each other with the folding area FA1 interposed therebetween. According to an embodiment, the display device DD-a may include a first non-folding area NFA1 and a second non-folding area NFA2 spaced apart from the first non-folding area NFA1 with the folding area FA1 interposed therebetween in the second directional axis DR2. As an example, the first non-folding area NFA1 may be adjacent to one side of the folding area FA1 in the first directional axis DR1, and the second non-folding area NFA2 may be adjacent to the other side of the folding area FA1 in the first directional axis DR1.

FIGS. 2A to 2C show the display device DD-a including one folding area FA1 as a representative example, however, the present disclosure should not be limited thereto or thereby. According to an embodiment, the display device DD-a may include a plurality of folding areas. As an example, the display device may include two or more folding areas and three or more non-folding areas disposed with the folding areas interposed therebetween.

Referring to FIG. 2B, the display device DD-a may be folded with respect to a first folding axis FX1. The first folding axis FX1 may be an imaginary axis extending in the first directional axis DR1 that is substantially parallel to a direction in which a long side of the display device DD-a extends. The first folding axis FX1 may extend in the first directional axis DR1 on the first display surface FS.

The display device DD-a may be folded with respect to the first folding axis FX1 to be in the inwardly folded (in-folding) state where an area of the first display surface FS, which overlaps the first non-folding area NFA1, faces an area of the first display surface FS, which overlaps the second non-folding area NFA2. For example, the display device DD-a may be inwardly folded (in-folding) around the first folding axis FX1, aligning an area of the first display surface FS that overlaps the first non-folding area NFA1 with an area of the first display surface FS that overlaps the second non-folding area NFA2.

The second display surface RS may be viewed by the user when the display device DD-a is in the inwardly folded state. The second display surface RS may further include the electronic module area EMA in which an electronic module including various components is disposed, however, it should not be limited thereto or thereby.

Referring to FIG. 2C, the display device DD-a may be folded with respect to the first folding axis FX1 to be in an outwardly folded (out-folding) state where an area of the second display surface RS, which overlaps the first non-folding area NFA1, faces an area of the second display surface RS, which overlaps the second non-folding area NFA2. For example, as shown in FIG. 2C, the display device DD-a may be outwardly folded (out-folding) around the first folding axis FX1, aligning an area of the second display surface RS that overlaps the first non-folding area NFA1 with an area of the second display surface RS that overlaps the second non-folding area NFA2.

However, the display device DD-a should not be limited thereto or thereby. The display device DD-a may be folded with respect to a plurality of folding axes such that a portion of the first display surface FS and a portion of the second display surface RS may face each other, and the number of the folding axes and the number of non-folding areas should not be particularly limited.

Various electronic modules may be disposed in the electronic module area EMA. As an example, the electronic module may include at least one of a camera, a speaker, an optical sensor, and a thermal sensor. An external object may be sensed through the electronic module area EMA of the first display surface FS or the second display surface RS, or a sound signal, such as a voice, may be provided to the outside through the electronic module area EMA of the first display surface FS or the second display surface RS. In addition, the electronic module may include a plurality of components, and it should not be limited to a particular embodiment.

The electronic module area EMA may be surrounded by the active area F-AA and the peripheral area F-NAA, however, it should not be limited thereto or thereby. The electronic module area EMA may be defined in the active area F-AA, and the electronic module area EMA should not be particularly limited.

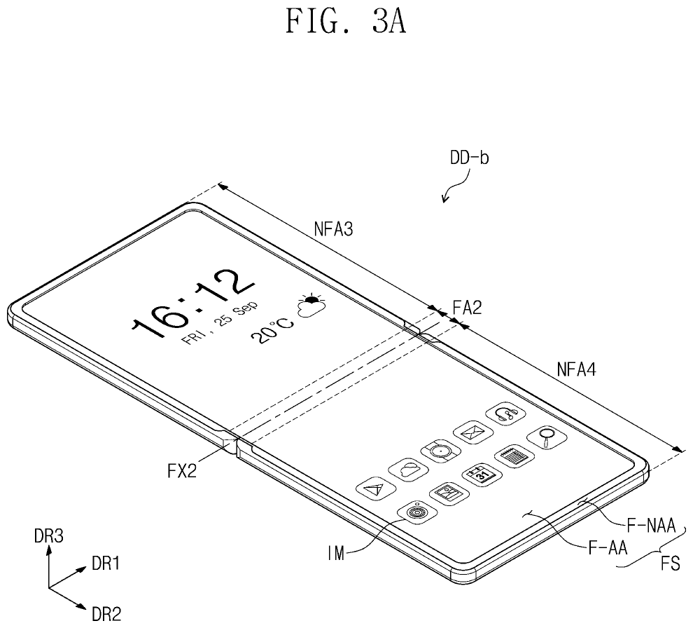

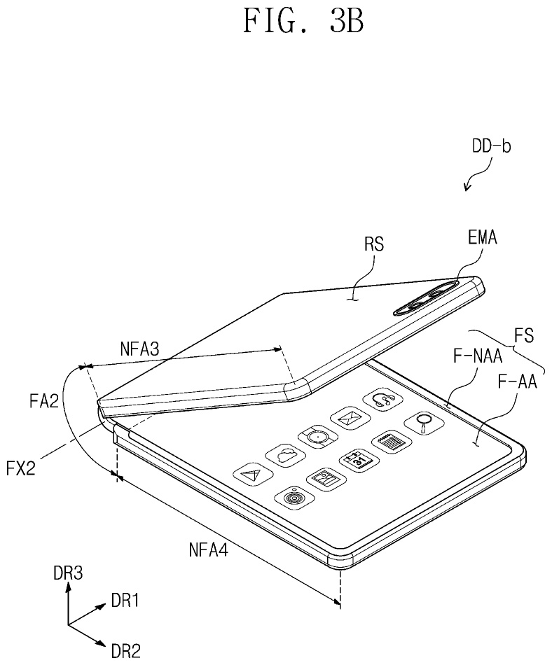

FIG. 3A is a perspective view of a display device DD-b in an unfolded state according to an embodiment of the present disclosure. FIG. 3B is a perspective view of the display device DD-b of FIG. 3A which is being inwardly folded according to an embodiment of the present disclosure. FIG. 3C is a perspective view of the display device DD-b of FIG. 3A which is being outwardly folded according to an embodiment of the present disclosure.

The display device DD-b may be folded with respect to a second folding axis FX2 extending in a direction substantially parallel to a first directional axis DR1. In FIG. 3B, the second folding axis FX2 extends substantially parallel to a direction in which a short side of the display device DD-b extends, however, it should not be limited thereto or thereby.

According to an embodiment, the display device DD-b may include at least one folding area FA2 and non-folding areas NFA3 and NFA4. The non-folding areas NFA3 and NFA4 may be adjacent to the folding area FA2. The non-folding areas NFA3 and NFA4 may be spaced apart from each other with the folding area FA2 interposed therebetween. For example, the non-folding areas NFA3 and NFA4 may be adjacent to opposite sides of the folding area FA2, respectively.

The folding area FA2 may have a predetermined curvature and a radius of curvature. According to an embodiment, the display device DD-b may be inwardly folded (in-folding) such that a first non-folding area NFA3 and a second non-folding area NFA4 may face each other and a first display surface FS may not be exposed to the outside. In addition, referring to FIG. 3C, the display device DD-b may be outwardly folded (out-folding) such that the first display surface FS may be exposed to the outside.

According to an embodiment, the display device DD-b may include a second display surface RS, and the second display surface RS may be defined as a surface opposite to at least a portion of the first display surface FS. The second display surface RS may include an electronic module area EMA in which an electronic module including various components is disposed. In addition, an image may be displayed through at least a portion of the second display surface RS.

The first display surface FS may be viewed by the user in the unfolded state of the display device DD-b, and the second display surface RS may be viewed by the user in the inwardly folded state.

The display devices DD-a and DD-b may be configured to repeat the unfolding operation and the in-folding operation or to repeat the unfolding operation and the out-folding operation, however, the present disclosure should not be limited thereto or thereby. According to an embodiment, the display devices DD-a and DD-b may be selectively operated in any one of the unfolding operation, the in-folding operation, and the out-folding operation. In addition, in the case where the display devices DD-a and DD-b include a plurality of folding areas, at least one of the folding areas may be folded in a direction different from folding directions of the other folding areas. As an example, in the case where the display devices DD-a and DD-b include two folding areas, two non-folding areas disposed with one folding area interposed therebetween may be inwardly folded, and two non-folding areas disposed with the other folding area interposed therebetween may be outwardly folded.

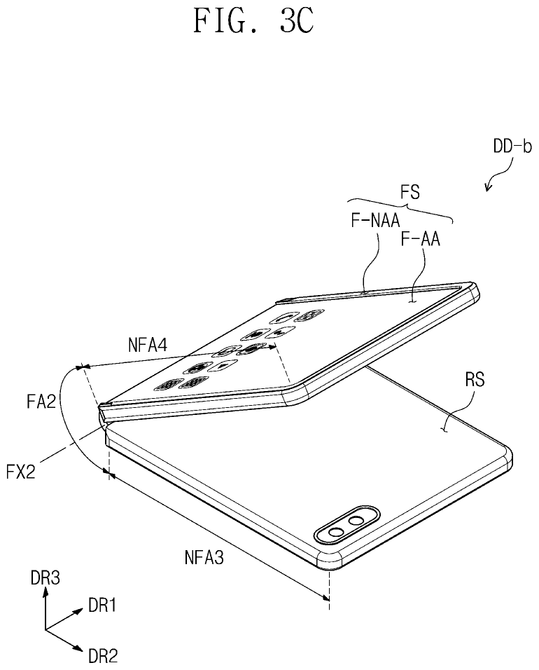

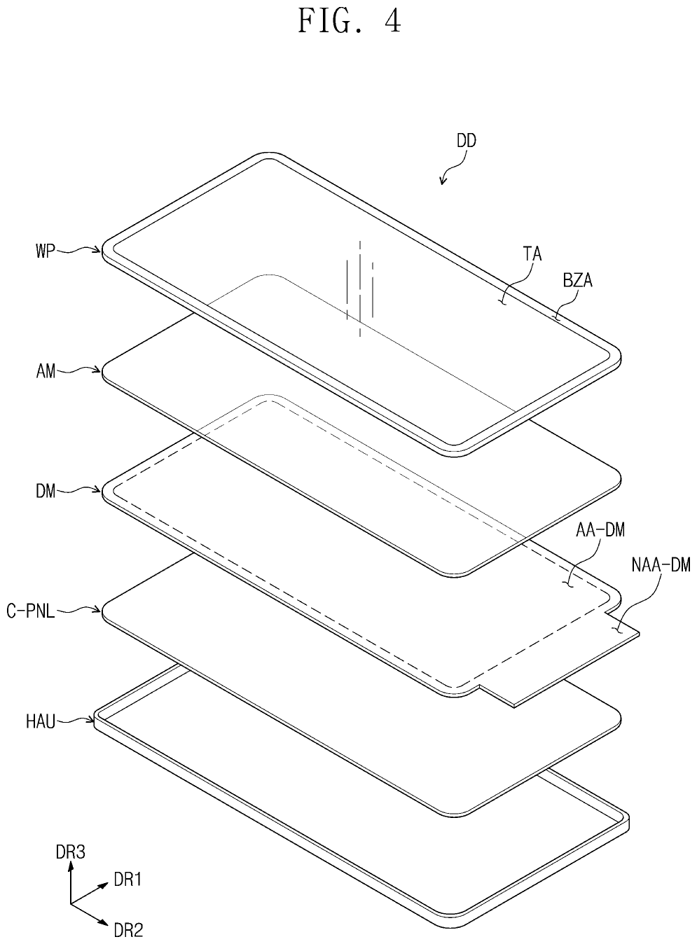

Hereinafter, a display device will be described based on the structure of the display device shown in FIG. 1. However, details on the display device described below may be applied to the foldable display device shown in FIGS. 2A to 3C. FIG. 4 is an exploded perspective view of the display device according to an embodiment of the present disclosure.

Referring to FIG. 4, the display device DD may include a display module DM, a window WP disposed on the display module DM, and an adhesive member AM disposed between the display module DM and the window WP. In addition, the display device DD may further include an impact resistance layer C-PNL that is disposed on a rear surface of the display module DM and protects the display module DM and a housing HAU in which the display module DM is accommodated.

In the display device DD shown in FIG. 4, the window WP and the housing HAU may be coupled to each other to provide an exterior of the display device DD. The housing HAU may be disposed under the display module DM. The housing HAU may include a material with a relatively high rigidity. As an example, the housing HAU may include a frame and/or a plate formed of a glass, plastic, or metal. The housing HAU may provide a predetermined accommodation space. The display module DM may be accommodated in the accommodation space and may be protected from external impacts.

The impact resistance layer C-PNL may be disposed between the housing HAU and the display module DM. The impact resistance layer C-PNL may prevent the display module DM from being pressed and plastic-deformed by external impact and force. The impact resistance layer C-PNL may improve an impact resistance of the display device DD. The impact resistance layer C-PNL may include or may be formed of a sponge, a foam, or an elastomer. In addition, the impact resistance layer C-PNL may include or may be formed of at least one of an acrylic-based polymer, a urethane-based polymer, a silicon-based polymer, and an imide-based polymer, however, it should not be limited thereto or thereby.

The display module DM may be activated in response to electrical signals. The activated display module DM may display the image IM (refer to FIG. 1) through the display area DA (refer to FIG. 1) of the display device DD. The display module DM may include an active area AA-DM and a peripheral area NAA-DM. The active area AA-DM may be an area activated in response to the electrical signals. The peripheral area NAA-DM may be adjacent to at least one side of the active area AA-DM. A driving circuit or a driving line may be arranged in the peripheral area NAA-DM to drive the active area AA-DM.

According to an embodiment, the adhesive member AM may be manufactured using the method, which will be described later. The adhesive member AM may have excellent impact resistance and adhesive reliability. Accordingly, the display device DD including the adhesive member AM may also have excellent impact resistance and excellent bonding reliability.

The window WP may include a transmissive area TA and a bezel area BZA. The transmissive area TA may overlap at least a portion of the active area AA-DM of the display module DM. The transmissive area TA may be an optically transparent area. The image IM (refer to FIG. 1) may be provided to a user through the transmissive area TA.

The bezel area BZA may be an area having a relatively lower transmittance than that of the transmissive area TA. The bezel area BZA may define a shape of the transmissive area TA. The bezel area BZA may be adjacent to the transmissive area TA and may surround the transmissive area TA.

The bezel area BZA may have a predetermined color. The bezel area BZA may cover the peripheral area NAA-DM of the display module DM to prevent the peripheral area NAA-DM from being viewed from the outside, however, this is merely an example. The bezel area BZA may be adjacent to only one side of the transmissive area TA or at least a portion thereof may be omitted.

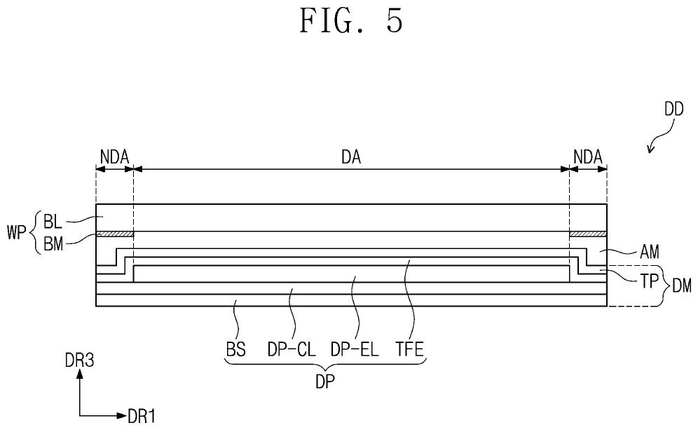

FIG. 5 is a cross-sectional view of the display device DD according to an embodiment of the present disclosure. FIG. 5 shows a cross-section of the display module DM, the adhesive member AM, and the window WP of FIG. 4.

Referring to FIG. 5, the display module DM may include a display panel DP and an input sensing unit TP disposed on the display panel DP. The display panel DP may include a base substrate BS, a circuit layer DP-CL disposed on the base substrate BS, a display element layer DP-EL disposed on the circuit layer DP-CL, and an encapsulation layer TFE covering the display element layer DP-EL. The adhesive member AM may be disposed between the display panel DP and the window WP.

The display panel DP shown in FIG. 5 is merely an example, and the structure of the display panel DP should not be limited thereto or thereby. As an example, the display panel DP may include a liquid crystal display element, and in this case, the encapsulation layer TFE may be omitted.

The base substrate BS may provide a base surface on which the circuit layer DP-CL is disposed. The base substrate BS may be a flexible substrate that is bendable, foldable, or rollable. The base substrate BS may be a glass substrate, a metal substrate, or a polymer substrate. However, the embodiment should not be limited thereto or thereby, and the base substrate BS may be an inorganic layer, an organic layer, or a composite material layer thereof.

The circuit layer DP-CL may include an insulating layer, a semiconductor pattern, a conductive pattern, and a signal line. As an example, the circuit layer DP-CL may include a switching transistor and a driving transistor to drive a light emitting element (not shown) of the display element layer DP-EL.

The display element layer DP-EL may include the light emitting element (not shown) emitting a light. For example, the light emitting element (not shown) may include an organic light emitting material, an inorganic light emitting material, an organic-inorganic light emitting material, a quantum dot, a quantum rod, a micro-LED, or a nano-LED.

The encapsulation layer TFE may be disposed on the display element layer DP-EL. The encapsulation layer TFE may protect the display element layer DP-EL from moisture, oxygen, and/or a foreign substance such as dust particles. The encapsulation layer TFE may include at least one inorganic layer. In addition, the encapsulation layer TFE may include at least one organic layer and at least one inorganic layer. As an example, the encapsulation layer TFE may include an inorganic layer, an organic layer, and an inorganic layer, which are sequentially stacked on each other.

The input sensing unit ISP may be disposed on the display panel DP. As an example, the input sensing unit ISP may be disposed directly on the display panel DP. The input sensing unit ISP may sense an external input, may convert the external input to a predetermined input signal, and may provide the input signal to the display panel DP. As an example, the input sensing unit ISP of the display device DD may be a touch sensing unit sensing a touch event. The input sensing unit TP may sense a direct touch of a user, an indirect touch of the user, a direct touch of an object, or an indirect touch of the object.

The input sensing unit TP may sense at least one of a position of the touch event applied from the outside of the input sensing unit TP and an intensity (pressure) of the touch event applied from the outside of the input sensing unit TP. The input sensing unit TP may have various structures or may include various materials, and it should not be particularly limited. The input sensing unit TP may include a plurality of sensing electrodes (not shown) to sense the external input. The sensing electrodes (not shown) may sense the external input in a capacitive manner. The display panel DP may receive the input signal from the input sensing unit TP and may generate an image corresponding to the input signal.

The display module DM may be attached to the window WP by the adhesive member AM. The adhesive member AM may be an adhesive layer such as an optically clear adhesive (OCA) or an adhesive resin such as an optically clear resin (OCR). For example, the optically clear adhesive may include UV-curing optical adhesives, epoxy-based optically clear adhesives, silicone-based optically clear adhesives, acrylic-based optically clear adhesives, polyurethane-based optically clear adhesives, cyanoacrylate-based optically clear adhesives. In some embodiments where the optically clear adhesive includes photoinitiators, when the adhesive is exposed to UV light, the photoinitiators absorb the UV radiation and undergo a chemical reaction that generates free radicals. These free radicals initiate the polymerization process, causing the liquid adhesive to cross-link and form a solid, transparent material. In such curing process, the amount of the photoinitiators may determine the hardness of the cured adhesive layer. In some embodiments, different types of photoinitiators may be used in UV-curing adhesives, and the choice of photoinitiators may impact the curing speed, depth of cure, and other properties of the adhesive such as hardness. In some embodiments, the photoinitiators may include any one of 1-Hydroxy-cyclohexyl-phenyl-ketone, 2-hydroxy-2-methyl-1-(4-tert-butyl)phenylpropanone, (4-methylphenyl)[4-(2-methylpropyl)phentyl]-,hexafluorophosphate(1-) inpropylene carbonate, 2-Benzyl-2-dimethylamino-1-(4-morpholinophenyl)-butanone-1, Benzophenone, 2-Hydroxy-2-methyl-1-phenyl-propan-1-one, Methylbenzoylformate, 2,4,6-Trimethylbenzoyl diphenylphosphine oxide, Bis(2,4,6-Trimethylbenzoyl)-Phenylphosphineoxide, Di-ester of carboxymethoxy thioxanthone and polytetramethyleneglycol 250, and Bis(2,6-dimethoxybenzoyl)-2,4,4- or a combination thereof. The adhesive member AM may be provided in a film form. The adhesive member AM may be disposed directly on the display module DM. The adhesive member AM may be disposed directly on the input sensing unit TP included in the display module DM.

The window WP may include a base layer BL and a printed layer BM. Although not shown in figures, the window WP may further include at least one functional layer (not shown) disposed on the base layer BL. As an example, the functional layer (not shown) may be a hard coating layer or an anti-fingerprint coating layer, but it should not be limited thereto or thereby.

The base layer BL may be a glass or plastic substrate. According to an embodiment, the base layer BL may be formed of a flexible polymer resin. As an example, the base layer BL may include or may be formed of polyimide, polyacrylate, polymethylmethacrylate, polycarbonate, polyethylenenaphthalate, polyvinylidene chloride, polyvinylidene difluoride, polystyrene, ethylene vinyl alcohol copolymer, or a combination thereof.

The printed layer BM may be disposed on one surface of the base layer BL. The printed layer BM may be disposed on a lower surface of the base layer BL, which is adjacent to the display module DM. The printed layer BM may be disposed at an edge of the base layer BL. The printed layer BM may be an ink printed layer. In addition, the printed layer BM may be a layer formed of a pigment or dye. In the window WP, the printed layer BM may be provided in the bezel area BZA.

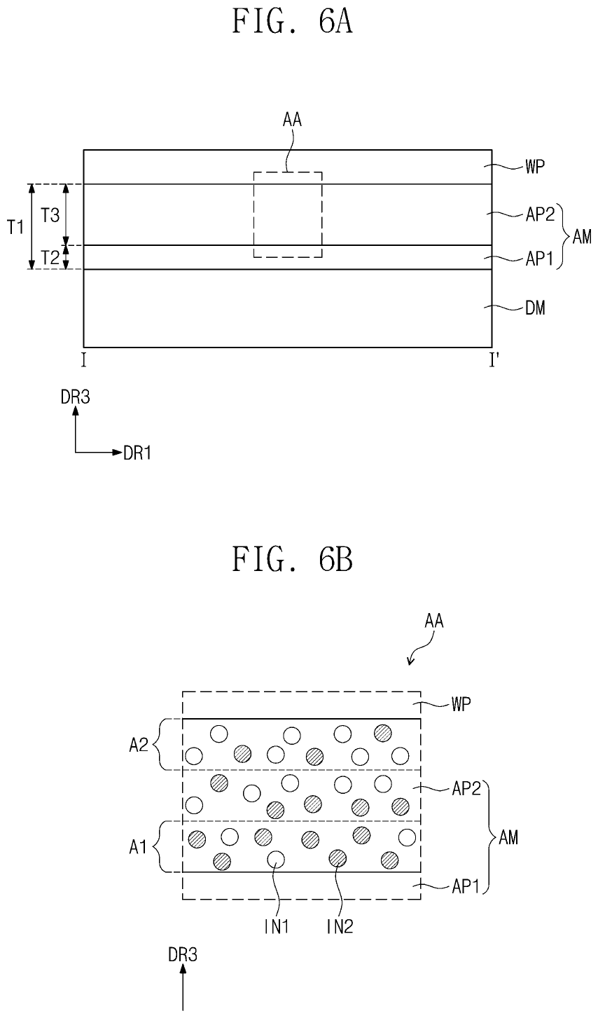

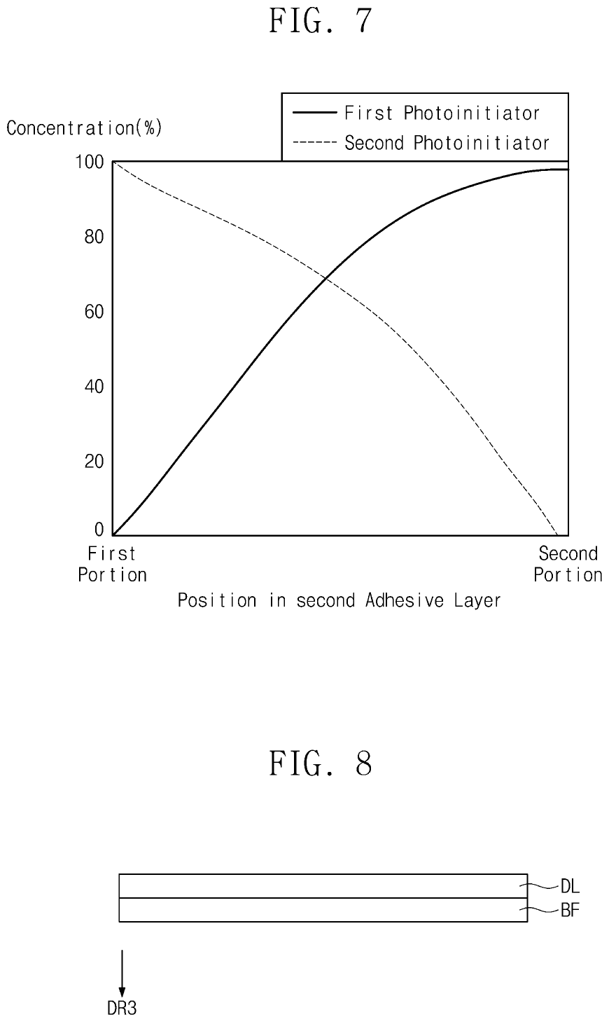

FIG. 6A is a view of the display device according to an embodiment of the present disclosure. FIG. 6B is an enlarged view of a portion of the display device according to an embodiment of the present disclosure. FIG. 7 is a graph illustrating a concentration of first and second photoinitiators included in a second adhesive layer according to an embodiment of the present disclosure. FIG. 6B is an enlarged view corresponding to a portion AA shown in FIG. 6A. In some embodiments, the first and second photoinitiators may be different from each other in kind. The present disclosure is not limited thereto. For example, the first and second photoinitiators may be the same as each other in kind.

Referring to FIGS. 6A and 6B, the adhesive member AM may be disposed directly on the display module DM. For example, no other components may be disposed between the display module DM and the adhesive member AM. The window WP may be disposed directly on the adhesive member AM. For example, no other components may be disposed between the adhesive member AM and the window WP. Only the adhesive member AM may be disposed between the display module DM and the window WP. A polarizing plate may not be disposed between the display module DM and the window WP, however, this is merely an example. According to an embodiment, other components may be further disposed between the display module DM and the adhesive member AM.

The adhesive member AM may include a first adhesive layer AP1 and a second adhesive layer AP2. The first adhesive layer AP1 may be disposed directly on the display module DM. For example, no other components may be disposed between the display module DM and the first adhesive layer AP1.

The second adhesive layer AP2 may be disposed between the first adhesive layer AP1 and the window WP. The second adhesive layer AP2 may be disposed directly on the first adhesive layer AP1. For example, no other components may be disposed between the first adhesive layer AP1 and the second adhesive layer AP2. The present disclosure, however, is not limited thereto. In some embodiments, other components may be disposed between the first adhesive layer AP1 and the second adhesive layer AP2.

The first adhesive layer AP1 may have a first storage modulus at a temperature of about 25° C. The second adhesive layer AP2 may include a first portion A1 adjacent to the first adhesive layer AP1 and a second portion A2 spaced apart from the first portion A1 in a thickness direction. For example, the first adhesive layer AP1 and the second adhesive layer A2 may be stacked on each other. The thickness direction may correspond to a stacking direction of the first and second adhesive layers AP1 and AP2. In some embodiments, the thickness direction may correspond to a direction perpendicular to an upper surface of a display module DM. For example, each of the first adhesive layer AP1 and the second adhesive layer AP2 may extend in a first horizontal direction (e.g., a first directional axis DR1 of FIG. 4) and a second horizontal direction (e.g., a second directional axis DR2 of FIG. 4) different from the first horizontal direction, and the thickness direction (i.e., a third directional axis DR3 of FIG. 4 or a vertical direction) is perpendicular to the first and second horizontal directions. The first portion A1 may have a second storage modulus at a temperature of about 25° C. The second portion A2 may have a third storage modulus smaller than the second storage modulus at a temperature of about 25° C. Hereinafter, the term “storage modulus” may indicate the storage modulus at the temperature of about 25° C., and thus, the temperature will not be stated when describing the storage modulus.

Meanwhile, the second storage modulus may be greater than the first storage modulus. Accordingly, the adhesive member AM may have a modulus distribution that follows a low-high-low sequence in the thickness direction. For example, as the adhesive member AM includes the first adhesive layer AP1 having the first storage modulus and the second adhesive layer AP2 including the first portion A1 having the second storage modulus and the second portion A2 having the third storage modulus, the modulus distribution that follows the low-high-low sequence may appear in the thickness direction. As a result, the adhesive member AM may have excellent impact resistance.

The first storage modulus may be equal to or greater than about 0.03 MPa and equal to or smaller than about 0.05 Mpa. For example, first storage modulus may be a value selected from a range of about 0.03 MPa to about 0.05 Mpa. The second storage modulus may be equal to or greater than about 0.1 MPa and equal to or smaller than about 0.4 MPa. For example, the second storage modulus may be a value selected from a range of about 0.1 MPa to about 0.4 MPa. The third storage modulus may be equal to or greater than about 0.03 MPa and equal to or smaller than about 0.05 MPa. For example, the third storage modulus may be a value selected from a range of about 0.03 MPa to about 0.05 MPa. With the numerical range of the first storage modulus to the third storage modulus presented above, the adhesive member AM may have excellent impact resistance.

According to an embodiment, the second adhesive layer AP2 may be provided in a single layer. For example, the second adhesive layer AP2 may include the first portion A1 and the second portion A2, which are defined in the single layer and have different storage moduli from each other. Accordingly, as the adhesive member AM includes the second adhesive layer AP2 including the first portion A1 and the second portion A2, which have different storage moduli from each other, the adhesive member AM may have the impact resistance similar to that of a structure including two layers having different storage moduli from each other.

In addition, as the adhesive member AM includes the second adhesive layer AP2 including the first portion A1 and the second portion A2, which have different storage moduli from each other, a process of forming the adhesive member AM may be simplified compared with a process of forming two adhesive layers having different storage moduli from each other.

As the adhesive member AM includes the second adhesive layer AP2 including the first portion A1 and the second portion A2, which have different storage moduli from each other, a bonding reliability between the display module DM and the window WP may be improved. In detail, as the number of adhesive layers included in the adhesive member AM decreases, defects such as a separation between layers may be reduced, and thus, the bonding reliability between the display module DM and the window WP may be improved by the adhesive member AM.

Meanwhile, the storage modulus of the second adhesive layer AP2 may decrease from the first portion A1 to the second portion A2. The storage modulus of the second adhesive layer AP2 may decrease from a portion adjacent to the first adhesive layer AP1 to a portion adjacent to the window WP.

The adhesive member AM may have a thickness T1 equal to or greater than about 150 μm and equal to or smaller than about 200 μm. For example, the adhesive member AM may have a thickness T1 selected from a range of about 150 μm to about 200/m. Accordingly, the adhesive member AM may have excellent impact resistance and superior bonding reliability. When the thickness T1 of the adhesive member AM is smaller than about 150 μm, the impact resistance of the adhesive member AM may be lowered. When the thickness T1 of the adhesive member AM is greater than about 200 μm, the thickness of the display device DD may increase. In addition, when the thickness T1 of the adhesive member AM is greater than about 200 Mm, a defect in which the adhesive member AM flows outside an edge of the display module DM and an edge of the window WP may occur during the bonding process between the display module DM and the window WP. For example, when the thickness T1 of the adhesive member AM is greater than about 200 μm, there is a risk of the adhesive member AM flowing outside the edges of the display module DM and the window WP during the bonding process.

The first adhesive layer AP1 may have a thickness T2 equal to or greater than about 25 μm and equal to or smaller than about 60 μm. For example, the first adhesive layer AP1 may have a thickness selected from a range of about 25 μm to about 60/m. Accordingly, the adhesive member AM including the first adhesive layer AP1 may have excellent impact resistance and superior bonding reliability. When the thickness T2 of the first adhesive layer AP1 is smaller than about 25 μm, the impact resistance of the first adhesive layer AP1 may be lowered. When the thickness T2 of the first adhesive layer AP1 is greater than about 60/m, the thickness of the display device DD may increase. In addition, when the thickness T2 of the first adhesive layer AP1 is greater than about 60 μm, a defect in which the first adhesive layer AP1 flows outside the edge of the display module DM and the edge of the window WP may occur during the bonding process between the display module DM and the window WP. For example, when the thickness T2 of the first adhesive layer AP1 is greater than about 60 μm, there is a risk of the first adhesive layer AP1 flowing outside the edges of the display module DM and the window WP during the bonding process.

The second adhesive layer AP2 may have a thickness T3 equal to or greater than about 75 μm and equal to or smaller than about 150/m. For example, the second adhesive layer AP2 may have a thickness T3 selected from a range of about 75 μm to about 150/m. Accordingly, the adhesive member AM including the second adhesive layer AP2 may have excellent impact resistance and superior bonding reliability. When the thickness T3 of the second adhesive layer AP2 is smaller than about 75/m, the impact resistance of the second adhesive layer AP2 may be lowered. When the thickness T3 of the second adhesive layer AP2 is greater than about 150 Mm, the thickness of the display device DD may increase. In addition, when the thickness T3 of the second adhesive layer AP2 is greater than bout 150/m, a defect in which the second adhesive layer AP2 flows outside the edge of the display module DM and the edge of the window WP may occur during the bonding process between the display module DM and the window WP. For example, when the thickness T3 of the second adhesive layer AP2 is greater than about 150 μm, there is a risk of the second adhesive layer AP2 flowing outside the edges of the display module DM and the window WP during the bonding process.

Referring to FIGS. 6B and 7, the second adhesive layer AP2 may include a first photoinitiator IN1 and a second photoinitiator IN2. The first photoinitiator IN1 and the second photoinitiator IN2 may be different from each other. For example, the first photoinitiator IN1 and the second photoinitiator IN2 may absorb lights in different wavelength ranges. The first photoinitiator IN1 may include any one of 1-Hydroxy-cyclohexyl-phenyl-ketone, 2-hydroxy-2-methyl-1-(4-tert-butyl)phenylpropanone, (4-methylphenyl)[4-(2-methylpropyl)phentyl]-, hexafluorophosphate(1-) inpropylene carbonate, 2-Benzyl-2-dimethylamino-1-(4-morpholinophenyl)-butanone-1, Benzophenone, 2-Hydroxy-2-methyl-1-phenyl-propan-1-one, and Methylbenzoylformate, or a combination thereof. The second photoinitiator IN2 may include any one of 2,4,6-Trimethylbenzoyl diphenylphosphine oxide, Bis(2,4,6-Trimethylbenzoyl)-Phenylphosphineoxide, Di-ester of carboxymethoxy thioxanthone and polytetramethyleneglycol 250, and Bis(2,6-dimethoxybenzoyl)-2,4,4-trimethylpentylphosphine, or a combination thereof. In some embodiments, the first and second photoinitiators IN1 and IN2 may differ from each other in kind.

The first photoinitiator IN1 may absorb the light whose center wavelength is equal to or greater than about 220 nm and equal to or smaller than about 320 nm. For example, the first photoinitiator IN1 may absorb the light with a center wavelength selected from a range of about 220 nm to about 320 nm. The second photoinitiator IN2 may absorb the light whose center wavelength is equal to or greater than about 340 nm and equal to or smaller than about 440 nm. For example, the second photoinitiator IN2 may absorb the light with a center wavelength selected from a range of about 340 nm to about 440 nm.

In the second adhesive layer AP2, a concentration of the first photoinitiator IN1 relative to that of the second photoinitiator IN2 may increase from the first portion A1 to the second portion A2. In the second adhesive layer AP2, the concentration of the second photoinitiator IN2 relative to that of the first photoinitiator IN1 may decrease from the first portion A1 to the second portion A2. Hereinafter, in the present disclosure, the concentration of the photoinitiator may be defined as the relative concentration between the first photoinitiator and the second photoinitiator included in the second adhesive layer AP2.

In the second adhesive layer AP2, a portion where the concentration of the first photoinitiator IN1 is small may have the storage modulus greater than that of a portion where the concentration of the first photoinitiator IN1 is large. For example, the second storage modulus of the first portion A1 may be greater than the third storage modulus of the second portion A2. For example, when the concentration of the first photoinitiator IN1 increases in a vertical direction from the first portion A1 to the second portion A2, the storage modulus of the second adhesive layer AP2 may decreases in the vertical direction. When the concentration of the first photoinitiator IN1 decreases in the vertical direction from the first portion A1 to the second portion A2, the storage modulus of the second adhesive layer AP2 may increase in the vertical direction.

A relationship between the concentration of the first photoinitiator IN1 and the storage modulus will be described in detail in a method of manufacturing the second adhesive layer AP2 with reference to FIGS. 6A to 9B.

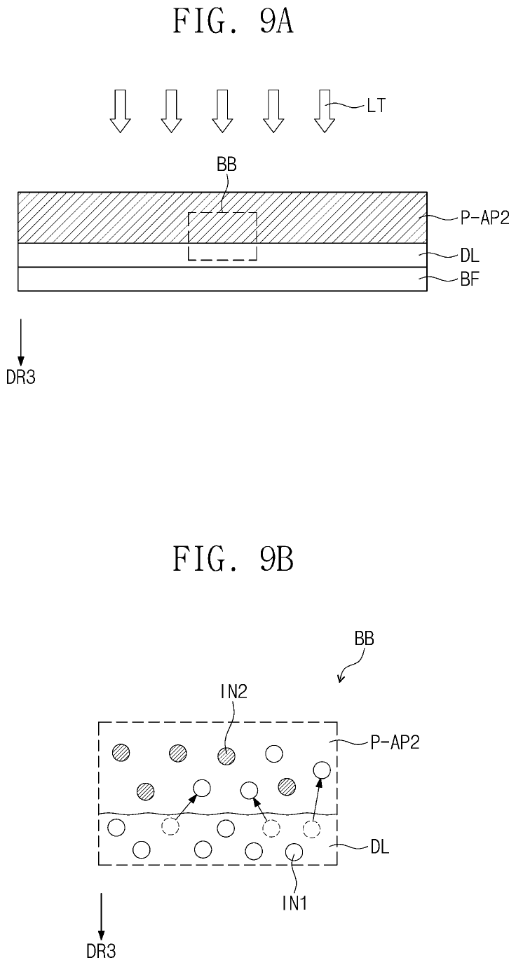

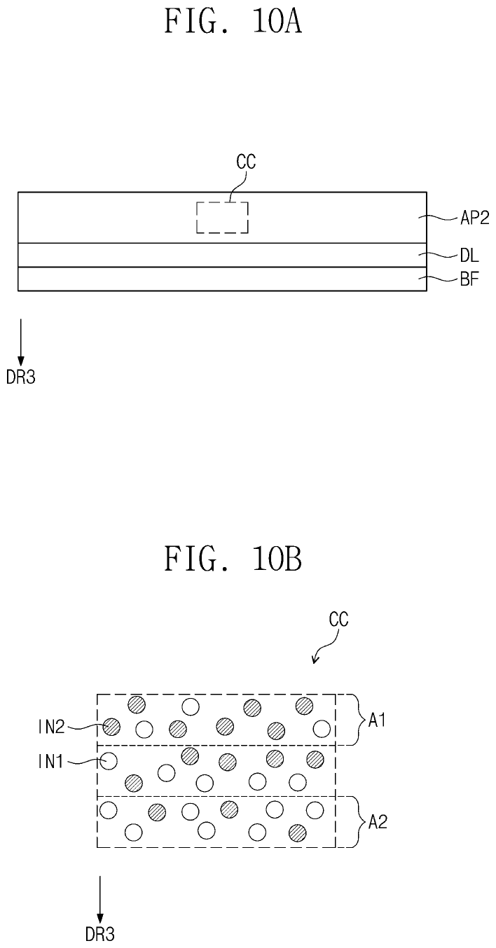

FIGS. 8 to 12 are views illustrating the method of manufacturing the adhesive member according to an embodiment of the present disclosure. In detail, FIGS. 8 to 9B are views illustrating a method of manufacturing the second adhesive layer. FIGS. 10A to 12 are views illustrating the manufacturing method of the adhesive member including the first and second adhesive layers.

FIG. 8 is a view illustrating a process of providing a first substrate BF with a coating layer DL. Referring to FIG. 8, the manufacturing method of the adhesive member may include the providing of the first substrate BF with the coating layer DL.

The first substrate BF may support a preliminary second adhesive layer P-AP2 (refer to FIG. 9A). The first substrate BF may be a polymer film. As an example, the first substrate BF may be formed of polyimide, polyacrylate, polymethylmethacrylate, polycarbonate, polyethylenenaphthalate, polyvinylidene chloride, polyvinylidene difluoride, polystyrene, ethylene vinyl alcohol copolymer, or a combination thereof. However, this is merely an example, and the present disclosure should not be limited thereto or thereby.

The coating layer DL may be disposed on the first substrate BF, and the coating layer DL may include the first photoinitiator IN1 (refer to FIG. 9B). The coating layer DL may be provided in a liquid state and may be coated on the first substrate BF.

FIG. 9A is a view of a process of providing the preliminary second adhesive layer on the coating layer. FIG. 9B is an enlarged view of an interface between the preliminary second adhesive layer and the coating layer. FIG. 9B is an enlarged view of a portion corresponding to an area BB of FIG. 9A.

Referring to FIGS. 9A and 9B, the manufacturing method of the adhesive member may include placing the preliminary second adhesive layer P-AP2 on the coating layer DL. The preliminary second adhesive layer P-AP2 may include the second photoinitiator IN2. The preliminary second adhesive layer P-AP2 may include the first photoinitiator IN1 derived from the coating layer DL. For example, the preliminary second adhesive layer P-AP2 may include the first photoinitiator IN1, which diffuses in from the coating layer DL. Accordingly, the preliminary second adhesive layer P-AP2 may include the first photoinitiator IN1 and the second photoinitiator IN2.

The manufacturing method of the adhesive member may include irradiating a light LT onto the preliminary second adhesive layer P-AP2 from the above the preliminary second adhesive layer P-AP2. The light LT may be a light in a short wavelength range. The light LT may be an ultraviolet light whose center wavelength is equal to or greater than about 220 nm and equal to or smaller than about 320 nm. For example, the light LT may be an ultraviolet light with a center wavelength selected from a range of about 220 nm to about 320 nm.

The first photoinitiator IN1 may absorb the light LT, and the second photoinitiator IN2 may not absorb the light LT. The first photoinitiator IN1 absorbing the light LT may cure the preliminary second adhesive layer P-AP2 and may become partially extinct (i.e., may be partially dissolved or may partially disappear). For example, a portion of the preliminary second adhesive layer P-AP2, which is adjacent to a light source (not shown) providing the light LT, may be cured, and the first photoinitiator IN1 included in which is adjacent to a light source (not shown) providing the light LT may become extinct (i.e., may be dissolved or may disappear).

FIG. 10A is a view of a cured second adhesive layer. FIG. 10B is an enlarged view of a portion of the cured second adhesive layer. FIG. 10B is an enlarged view of a portion corresponding to an area CC of FIG. 10A.

Referring to FIGS. 10A and 10B, the second adhesive layer AP2 may include the first portion A1 in which the concentration of the first photoinitiator IN1 is smaller than the concentration of the second photoinitiator IN2 and the second portion A2 in which the concentration of the first photoinitiator IN1 is greater than the concentration of the second photoinitiator IN2. The first portion A1 may be placed closer to which is adjacent to a light source (not shown) providing the light LT than the second portion A2 is. The first portion A1 may have the storage modulus greater than that of the second portion A2.

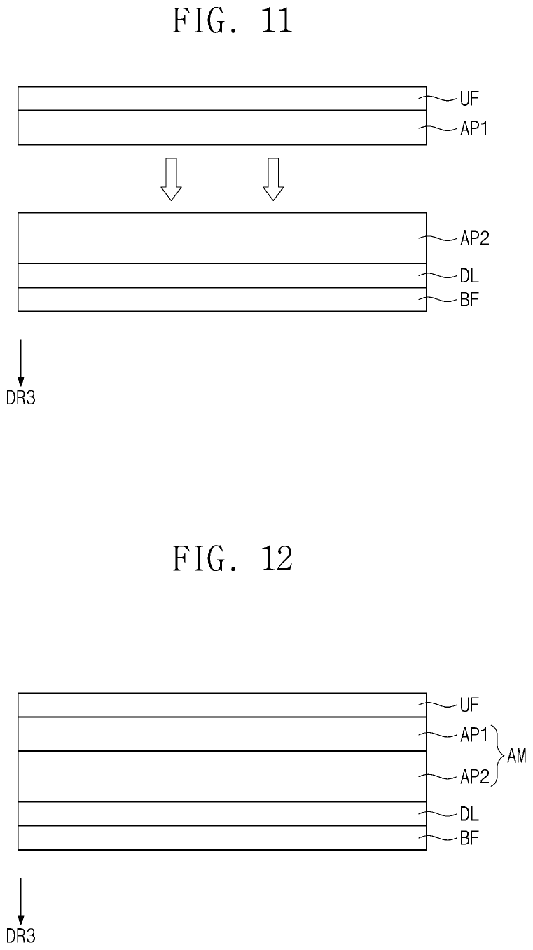

FIG. 11 is a view of a process of providing the first adhesive layer on the second adhesive layer. FIG. 12 is a view of the adhesive member manufactured by providing the first adhesive layer on the second adhesive layer.

Referring to FIGS. 11 and 12, the manufacturing method of the adhesive member may include providing the first adhesive layer AP1 disposed on a second substrate UF onto the second adhesive layer AP2. The first adhesive layer AP1 may be disposed on the second substrate UF. The second substrate UF may support the first adhesive layer AP1. The second substrate UF may be a polymer film. As an example, the second substrate UF may be formed of polyimide, polyacrylate, polymethylmethacrylate, polycarbonate, polyethylenenaphthalate, polyvinylidene chloride, polyvinylidene difluoride, polystyrene, ethylene vinyl alcohol copolymer, or combinations thereof. However, this is merely an example, and the present disclosure should not be limited thereto or thereby.

As the manufacturing method of the adhesive member includes the providing of the second adhesive layer AP2 on the first adhesive layer APIthe adhesive member AM having a storage modulus distribution that follows a low-high-low sequence in the thickness direction may be provided.

Hereinafter, the display device according to an embodiment of the present disclosure will be described in detail with reference to example embodiments and comparative examples. The example and comparative embodiments described below are examples to help understanding of the present disclosure, and the scope of the present disclosure should not be limited thereto or thereby.

### [Ball Drop Test Condition]

The ball used in the ball drop test has a weight of about 0.5 g, and the ball is dropped in the direction toward the display module from a height spaced 5 cm apart from the display module.

### [Ball Drop Test Evaluation Criteria]

The ball drop test is conducted to assess the display device's durability and the impact resistance of the adhesive member. In the ball drop test, the higher a minimum height at which a damage occurs on the display module after dropping the ball onto it, the greater the impact resistance of the adhesive member. The minimum height is obtained by calculating an average height after performing the ball drop tests twenty times.

### [Ball Drop Test Evaluation Result]

Table 1 below represents physical properties of the OCA layer used in experiments.

TABLE 1

| adhesive layer type | storage modulus (MPa, 25° C.) |
|---|---|
| A | 0.03 |
| B | 0.05 |
| C | 0.14 |
| D | 0.25 |

Table 2 below shows the ball drop height according to the adhesive member of each of comparative example 1 to comparative example 11 and example embodiment 1 and example embodiment 2. A stack structure of a display panel is based on the display panel shown in FIG. 5. A stack structure of the adhesive member is described in the order of a portion adjacent to the display panel/an intermediate portion/a portion adjacent to the window. For example, the stack structure of the adhesive member is described in the sequence of the portion adjacent to the display panel, followed by the intermediate portion, and finally, the portion adjacent to the window. In the first comparative example 1, the stack structure of adhesive members is represented using a notation of A/A/A. The first “A” represents the adhesive member adjacent to the display panel, and the second “A” represents the adhesive member corresponding to the intermediate portion, and the third “A” represents the portion adjacent to the window.

TABLE 2

| | Stack structure of | Ball drop |
|---|---|---|
| | adhesive members | height (cm) |
| comparative example 1 | A/A/A | 5 |
| comparative example 2 | B/B/B | 4.3 |
| comparative example 3 | C/C/C | 3.2 |
| comparative example 4 | D/D/D | 3 |
| comparative example 5 | B/B/D | 6.1 |
| comparative example 6 | B/D/D | 5.2 |
| comparative example 7 | D/B/B | 3.3 |
| comparative example 8 | D/D/B | 3 |
| comparative example 9 | B/D/B | 5.4 |
| comparative example 10 | C/D/C | 4 |
| comparative example 11 | D/A/D | 3.0 |
| example embodiment 1 | A/C/A | 8.4 |
| example embodiment 2 | B/C/B | 6.3 |

Referring to Table 2, when the adhesive member has the stack structure of a low modulus layer/a high modulus layer/a low modulus layer, the impact resistance is the most excellent. For example, according to Table 2, the stack structure of the adhesive members having a low modulus layer/a high modulus layer/a low modulus layer exhibits the highest level of impact resistance. In detail, the stack of adhesive members in which the adhesive layers respectively adjacent to the display panel and the window have the storage modulus selected from a range of about 0.03 MPa to about 0.05 MPa at the temperature of about 25° C. and the intermediate adhesive layer has the storage modulus selected from a range of about 0.1 MPa to about 0.24 MPa at the temperature of about 25° C. may have excellent impact resistance.

The adhesive member may include the first adhesive layer with the low modulus in the portion adjacent to the display panel and the second adhesive layer including the first portion with the high modulus in the portion adjacent to the first adhesive layer and the second portion with the low modulus in the portion adjacent to the window, and thus, the stack structure of a low modulus layer/a high modulus layer/a low modulus layer may be implemented using two adhesive layers. Accordingly, the display device may have excellent impact resistance as shown by embodiment example 1 and embodiment example 2 in Table 2.

Although the embodiments of the present disclosure have been described, it is understood that the present disclosure should not be limited to these embodiments but various changes and modifications can be made by one ordinary skilled in the art within the spirit and scope of the present disclosure as hereinafter claimed.

Therefore, the disclosed subject matter should not be limited to any single embodiment described herein, and the scope of the present inventive concept shall be determined according to the attached claims.

What is claimed is:

1. An adhesive member comprising:
a first adhesive layer extending in a first horizontal direction and a second horizontal direction different from the first horizontal direction and having a first storage modulus at a temperature of about 25° C.; and
a second adhesive layer extending in the first and second horizontal directions and disposed directly on the first adhesive layer and comprising a first portion adjacent to the first adhesive layer and having a second storage modulus greater than the first storage modulus at the temperature of about 25° C. and a second portion spaced apart from the first portion in a vertical direction perpendicular to the first and second horizontal directions and having a third storage modulus smaller than the second storage modulus at the temperature of about 25° C.

2. The adhesive member of claim 1,
wherein the second adhesive layer has a storage modulus that increases from the second portion to the first portion.

3. The adhesive member of claim 1,
wherein the first storage modulus has a value selected from a range of about 0.03 MPa to about 0.05 MPa at the temperature of about 25° C.

4. The adhesive member of claim 1,
wherein the second storage modulus has a value selected from a range of about 0.1 MPa to about 0.4 MPa at the temperature of about 25° C., and
wherein the third storage modulus has a value selected from a range of about 0.03 MPa to about 0.05 MPa at the temperature of about 25° C.

5. The adhesive member of claim 1,
wherein the adhesive member has a thickness having a value selected from a range of about 150 micrometers to about 200 micrometers.

6. The adhesive member of claim 1,
wherein the first adhesive layer has a thickness having a value selected from a range of about 25 micrometers to about 60 micrometers.

7. The adhesive member of claim 1,
wherein the second adhesive layer has a thickness having a value selected from a range of about 75 micrometers to about 150 micrometers.

8. The adhesive member of claim 1,
wherein the second adhesive layer is a single layer.

9. The adhesive member of claim 1,
wherein the second adhesive layer comprises:
a first photoinitiator absorbing a light with a center wavelength selected from a range of about 220 nanometers to about 320 nanometers; and
a second photoinitiator absorbing a light with a center wavelength selected from a range of about 340 nanometers to about 440 nanometers.

10. The adhesive member of claim 9,
wherein the first photoinitiator of the first portion has a concentration greater than a concentration of the first photoinitiator of the second portion, and
wherein the second photoinitiator of the first portion has a concentration smaller than a concentration of the second photoinitiator of the second portion.

11. The adhesive member of claim 10,
wherein the concentration of the first photoinitiator decreases from the first portion to the second portion.

12. The adhesive member of claim 10,
wherein the concentration of the second photoinitiator increases from the first portion to the second portion.

13. A display device comprising:
a display module;
a window disposed on the display module; and
an adhesive member disposed between the display module and the window, the adhesive member comprising:
a first adhesive layer disposed adjacent to the display module and having a first storage modulus at a temperature of about 25° C.; and
a second adhesive layer disposed between the first adhesive layer and the window and comprising a first portion adjacent to the first adhesive layer and having a second storage modulus greater than the first storage modulus at the temperature of about 25° C. and a second portion disposed adjacent to the window and having a third storage modulus smaller than the second storage modulus at the temperature of about 25° C.

14. The display device of claim 13,
wherein the second adhesive layer has a storage modulus that increases from the second portion to the first portion.

15. The display device of claim 13,
wherein the first storage modulus has a value selected from a range of about 0.03 MPa to about 0.05 MPa at the temperature of about 25° C.

16. The display device of claim 13,
wherein the second storage modulus has a value selected from a range of about 0.1 MPa to about 0.4 MPa at the temperature of about 25° C., and
wherein the third storage modulus has a value selected from range of about 0.03 MPa to about 0.05 MPa at the temperature of about 25° C.

17. The display device of claim 13,
wherein the adhesive member has a thickness having a value selected from a range of about 150 micrometers to about 200 micrometers.

18. The display device of claim 13,
wherein the first adhesive layer has a thickness having a value selected from a range of about 25 micrometers to about 60 micrometers.

19. The display device of claim 13,
wherein the second adhesive layer has a thickness having a value selected from a range of about 75 micrometers to about 150 micrometers.

20. The display device of claim 13,
wherein the second adhesive layer is a single layer.

21. The display device of claim 13,
wherein the display module comprises a display panel and an input sensing unit disposed on the display panel, the adhesive member is disposed directly on the input sensing unit, and the window is disposed directly on the adhesive member.

22. The display device of claim 13,
wherein the second adhesive layer is disposed directly on the first adhesive layer.

23. The display device of claim 13,
wherein the second adhesive layer comprises:
a first photoinitiator absorbing a light having a center wavelength selected from a range of about 220 nanometers to about 320 nanometers; and
a second photoinitiator absorbing a light having a center wavelength selected from a range of about 340 nanometers to about 440 nanometers.

24. The display device of claim 13,
wherein a first photoinitiator of the first portion has a concentration greater than a concentration of a first photoinitiator of the second portion, and
wherein the second photoinitiator of the first portion has a concentration smaller than a concentration of the second photoinitiator of the second portion.

25. The display device of claim 24,
wherein the concentration of the first photoinitiator decreases from the first portion to the second portion.

26. The display device of claim 24,
wherein the concentration of the second photoinitiator increases from the first portion to the second portion.
